(19) United States
(12) Patent Application Publication
(10) Pub. No.: US 2026/0182405 A1
(43) Pub. Date: Jun. 25, 2026

(54) GLASS SUBSTRATE WITH CAVITY AND SEEDLESS THROUGH-GLASS VIAS

(71) Applicant: Intel Corporation, Santa Clara, CA (US)

(72) Inventors: Brandon Christian Marin, Gilbert, AZ (US); Whitney M. Bryks, Tempe, AZ (US); Gang Duan, Chandler, AZ (US); Jeremy D. Ecton, Gilbert, AZ (US); Jason Michael Gamba, Gilbert, AZ (US); Haifa Hariri, Phoenix, AZ (US); Sashi Shekhar Kandanur, Phoenix, AZ (US); Rahul Manepalli, Chandler, AZ (US); Srinivas Venkata Ramanuja Pietambaram, Chandler, AZ (US); Mohammad Mamunur Rahman, Gilbert, AZ (US); Bohan Shan, Chandler, AZ (US); Hiroki Tanaka, Gilbert, AZ (US); Jacob Vehonsky, Chandler, AZ (US)

(73) Assignee: Intel Corporation, Santa Clara, CA (US)

(21) Appl. No.: 19/001,276

(22) Filed: Dec. 24, 2024

(51) Int. Cl. H01L 23/498; H01L 21/768; H01L 23/08

(52) U.S. Cl. CPC H10W 70/635; H10W 20/043; H10W 70/66; H10W 76/18

(57) ABSTRACT

Glass substrates with cavities and seedless through-glass vias (TGVs), devices and systems formed thereon, and methods of forming the same, are disclosed herein. In one example, a substrate includes a glass layer with a rectangular prism volume, a cavity in the glass layer, and one or more vias extending between top and bottom surfaces of the glass layer. The vias are filled with a first conductive material, and the sidewalls of the vias are not lined with a second conductive material.

### BACKGROUND

Semiconductor substrates with glass cores—also referred to herein as glass substrates—are a promising alternative to substrates with organic cores (e.g., copper-clad laminates (CCLs)), particularly due to the high thermal stability, enhanced electrical properties, and flat and distortion-free surface provided by glass. Fabricating substrates with glass cores can be challenging, however, particularly due to the fragility of glass and low compatibility with other materials (e.g., coefficient of thermal expansion (CTE) mismatches, poor adhesion), which can lead to defects during manufacturing.

### BRIEF DESCRIPTION OF THE DRAWINGS

FIGS. 1A-D illustrate examples of glass substrates with a cavity and seedless through-glass vias (TGVs).

FIGS. 2A-B illustrate a simplified example of a glass substrate with a cavity and seedless TGVs.

FIGS. 3A-H illustrate an example process flow for forming a glass substrate with a cavity and seedless TGVs using a mask over the cavity.

FIGS. 4A-J illustrate an example process flow for forming a glass substrate with a cavity and seedless TGVs using a removable copper cavity plug.

FIGS. 5A-B illustrate an example of a glass substrate with tooling holes processed using the process flow of FIGS. 4A-J.

FIGS. 6A-H illustrate an example process flow for forming a glass substrate with a cavity and seedless TGVs using a preferential cavity fill.

FIG. 7 illustrates an example of an integrated circuit package that may incorporate a glass substrate with a cavity and seedless TGVs.

FIGS. 8A-B illustrate example systems that may incorporate a glass substrate with a cavity and seedless TGVs.

FIG. 9 illustrates a process flow for packaging integrated circuits on a glass substrate with a cavity and seedless TGVs.

FIGS. 10A-C illustrate an example of a glass substrate.

FIG. 11 illustrates a top view of a wafer and dies that may be included in a microelectronic assembly.

FIG. 12 illustrates a cross-sectional side view of an integrated circuit device assembly that may include a microelectronic assembly.

FIG. 13 illustrates a block diagram of an example electrical device that may include a microelectronic assembly.

### DETAILED DESCRIPTION

Semiconductor substrates with glass cores—also referred to herein as glass substrates—are a promising alternative to substrates with organic cores (e.g., copper-clad laminates (CCLs)), particularly due to the high thermal stability, enhanced electrical properties, and flat and distortion-free surface provided by glass. Fabricating substrates with glass cores can be challenging, however, particularly due to the fragility of glass and incompatibilities with other materials, such as coefficient of thermal expansion (CTE) mismatches, low adhesion, and so forth.

For example, through-glass vias (TGVs) are typically formed by drilling via holes through a glass core, lining the sidewalls of the via holes with a thin conductive material (e.g., ruthenium), referred to as the seed layer, and then filling the remaining area of the via holes with a conductive material (e.g., copper) using an electroplating process, referred to as the fill layer. The seed layer serves as a conductive surface on the TGV sidewalls, which is required by the electroplating process used to fill the remaining area of the TGVs in the conductive fill layer, and the seed layer also enhances adhesion between the fill layer and the TGV sidewalls in the glass core.

In some embodiments, for example, the seed layer may be formed by depositing a metal such as ruthenium (Ru) over the glass core, and the fill layer may be formed by growing a metal such as copper (Cu) from the seed layer using electroplating. In particular, ruthenium provides better adhesion to glass than copper, but copper has lower resistivity than ruthenium. In this manner, the ruthenium seed layer enables the copper fill layer to be formed using electroplating, while also improving adhesion between the copper fill layer and the TGV sidewalls in the glass core. Moreover, the copper fill layer provides a low-resistivity electrical path through the TGVs.

However, fully-filled copper TGVs with ruthenium seed layers tend to cause cracks in the glass core due to thermal treatments and high-temperature process steps that the substrate is exposed to during manufacturing. In particular, the copper fill in the TGVs deforms during processing due to CTE mismatches (e.g., between glass/copper) and plastic deformation of copper, which transfers stress to the glass core due to the strong adhesion the ruthenium seed layer provides between the glass core/copper fill, potentially causing the glass to crack. In some cases, a stress absorbing liner may be formed on the TGV sidewalls (e.g., before the seed layer) to absorb stress from copper deformation and reduce defects to the glass core. However, the seed layer and the stress absorbing liner both increase the manufacturing cost and complexity of glass substrates.

Further, if a glass core includes a cavity for embedded components, it can be challenging to avoid filling the cavity with metal (e.g., copper) when the TGV holes are electroplated. In some cases, for example, a glass core may include a cavity to embed passive components for power delivery. If the cavity is empty when the TGV holes are electroplated, however, the cavity will be filled with unwanted metal absent appropriate safeguards.

Currently, there are no high-volume manufacturing (HVM) solutions to address these various challenges for glass substrates.

Accordingly, this disclosure presents embodiments of glass substrates with cavities and seedless TGVs, devices and systems formed thereon, and methods of forming the same. In some embodiments, for example, a glass substrate may include a cavity and one or more seedless fully-filled TGVs, where the TGVs are not lined with a conductive seed layer (e.g., ruthenium or another metal) on the glass sidewalls, and the TGV fill material (e.g., copper or another metal) fits snug within the TGV holes without strong adhesion to the glass sidewalls. In this manner, when the TGV fill material deforms during high-temperature process steps, less stress is exerted on the glass sidewalls due to the relatively weak adhesion between the TGV fill material and the glass sidewalls, which leads to fewer defects (e.g., cracks, chips) in the glass core. As a result, no stress absorption liner is needed on the TGV sidewalls to protect the glass core from stress-induced defects, although in some cases, an optional stress absorption liner may be included for additional protection to the glass core.

In some embodiments, to manufacture the glass substrate, the bottom side or surface of the glass core is laminated with a copper foil, and the TGVs are electroplated from the bottom up using the copper foil as a seed layer (e.g., instead of lining the TGV sidewalls with a seed layer), removing the copper foil afterwards. Moreover, various approaches may be employed to avoid unwanted metal in the cavity when the TGVs are electroplated, including (i) closing off the cavity with a mask during the electroplating process, (ii) leaving the cavity open and optionally etching out unwanted metal after electroplating, or (iii) filling the cavity with another material before electroplating.

The described embodiments may provide various advantages, including lower risk of stress-related defects to the glass core, higher yield, and lower overall cost due to lower process complexity (e.g., no complex seed layers, stress absorption layers optional).

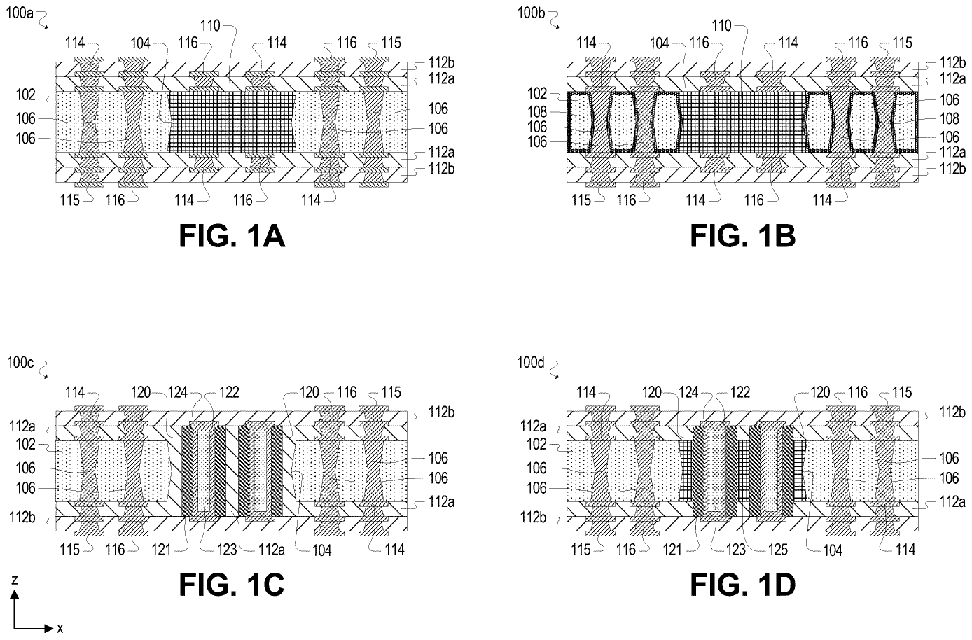

FIGS. 1A-D illustrate cross-section (x-z plane) views of glass substrates 100a-d with a cavity 104 and seedless through-glass vias (TGVs) 106. In some embodiments, the respective substrates 100a-d may be formed using the process flows described throughout this disclosure.

In the illustrated examples, substrates 100a-d include a glass core 102, a cavity 204 extending through the center of the glass core 102, and multiple seedless TGVs 106 extending through the glass core 102. Further, various integrated circuit (IC) components are embedded in the cavity 104 of the respective substrates 100a-d, as described further below.

Moreover, the TGVs 106 are not lined with a conductive seed layer (e.g., ruthenium or another metal) on the glass sidewalls of the core 102, and the TGV 106 fill material (e.g., copper or another metal) fits snug within the TGV 106 holes without strong adhesion to the glass sidewalls. In this manner, when the TGV 106 fill material deforms during high-temperature process steps, less stress is exerted on the glass sidewalls due to the relatively weak adhesion between the TGV 106 fill material and the glass sidewalls, which leads to fewer defects (e.g., cracks, chips) in the glass core 102.

The substrates 100a-d also include multiple dielectric layers 112a,b above and below the glass core 102 (e.g., Ajinomoto Build-up Film (ABF)), along with conductive traces 114, vias 116, and pads 115 throughout the dielectric layers 112ab. In actual embodiments, substrates 100a-d may also include one or more IC dies (not shown), which may be electrically coupled to pads 115 on the respective substrates 100a-d.

In FIG. 1A, substrate 100a includes embedded circuitry 110 within the cavity 104. The embedded circuitry 110 may include any type and/or combination of IC components, such as passive components for power delivery (e.g., inductors, capacitors, resistors) or heat dissipation (e.g., thermal vias), active components (e.g., embedded IC dies), etc. In some embodiments, for example, the cavity 104 may be filled with a dielectric and the particular IC components may be patterned and/or integrated within the dielectric.

In FIG. 1B, substrate 100b is similar to substrate 100a, except substrate 100b includes a stress absorption liner 108 (also referred to as a buffer or healing layer) on the glass sidewalls of the TGVs 106 to absorb stress from deformation of the TGV 106 fill material (e.g., copper) during processing. In particular, while the seedless TGVs 106 reduce the stress exerted on the glass core 102 during processing, a stress absorption liner 108 (e.g., a thin dielectric layer) may optionally be included to provide additional protection to the glass core 102. However, no conductive seed layer is present between the stress liner 108 and the TGV 106 sidewalls in the glass core 102.

In FIG. 1C, substrate 100c includes coaxial inductors 120 embedded within the cavity 104 of the glass core 102. In particular, the coaxial inductors 120 include plated through holes (PTHs) 122 with inner dielectric fill 123 (e.g., epoxy paste) and lids 124 (e.g., metal pads) patterned in dielectric layers 121 (e.g., magnetic paste) within the cavity 104. Moreover, the remaining area within the cavity 104 is filled with dielectric material from the first dielectric layer 112a on the glass core 102. In particular, the first dielectric layer 112a covers both sides of the glass core 102 and further extends through and fills the remaining area in the cavity 104.

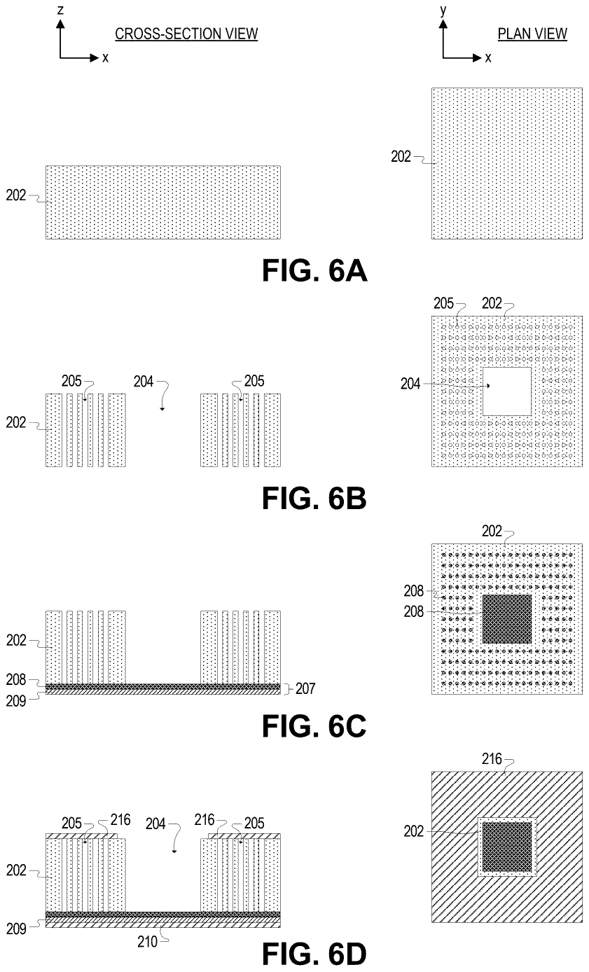

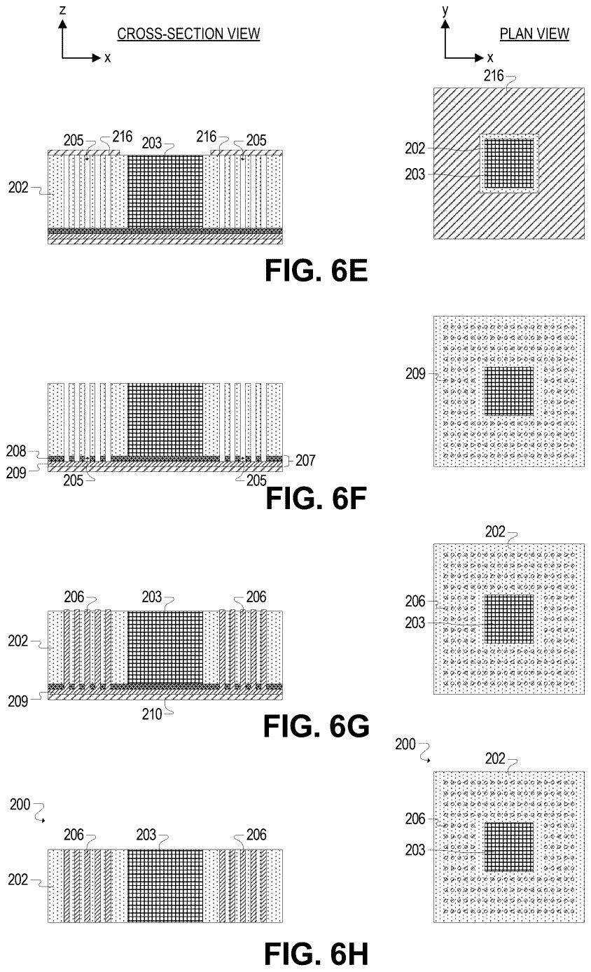

In FIG. 1D, substrate 100d is similar to substrate 100c, except the cavity 104 of substrate 100d includes a dielectric fill layer 125 (e.g., ABF) separate and distinct from the dielectric buildup layers 112a,b above and below the glass core 102. In some embodiments, substrate 100d may be formed using the seedless TGV process with preferential cavity fill described in connection with FIGS. 6A-H, where the cavity 104 is preferentially filled separately from the dielectric buildup layers 112a,b above and below the glass core 102, and the coaxial inductors 120 are then patterned through the cavity fill layer 125. In this manner, the dielectric cavity fill 125 and dielectric buildup layers 112a,b are distinct layers at different levels.

It should be appreciated that substrates 100a-d are merely shown as examples and numerous variations and alternative embodiments are also within the scope of this disclosure. In various embodiments, for example, certain elements of substrates 100a-d may be modified, replaced, rearranged, omitted, and/or added.

In various embodiments, for example, substrates 100a-d may include any number of cavities 104, TGVs 106, and dielectric buildup layers 112. In addition, the materials used to form the respective layers and elements of substrates 100a-d may vary in different embodiments. Moreover, any type or combination of components may be embedded in the cavity 104 of substrates 100a-d depending on the requirements of the particular application. Further, substrates 100a-d may include any type of substrate, such as a package substrate, interposer, or printed circuit board (PCB), among other examples.

Additional embodiments of substrates with cavities and seedless TSVs, along with process flows for forming the same, are described further throughout this disclosure. The concepts described above with respect to substrates 100a-d, including any modifications and variations thereof, also apply to the other embodiments described throughout this disclosure, and vice versa.

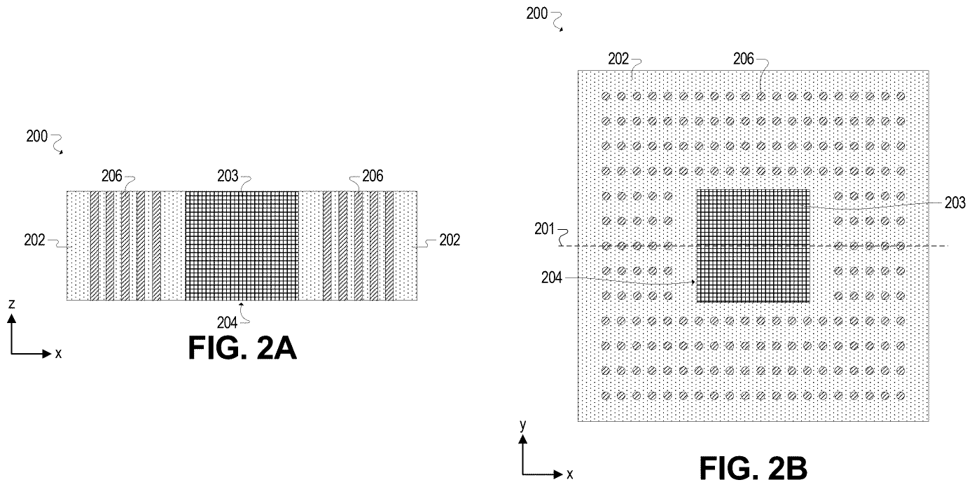

FIGS. 2A-B illustrate a simplified example of a glass substrate 200 with a cavity 204 and seedless through-glass vias (TGVs) 206. In the illustrated example, cross-section (x-z plane) and plan (x-y plane) views of substrate 200 are shown in FIG. 2A and FIG. 2B, respectively, where the cross-section view in FIG. 2A corresponds to the cut line 201 shown in FIG. 2B.

In the illustrated embodiment, glass substrate 200 includes a glass core 202, a cavity 204 extending through the center of the glass core 202, a cavity fill material 203 filling the cavity 204, and multiple seedless TGVs 206 extending through the glass core 202.

In actual embodiments, glass substrate 200 may also include various integrated circuit (IC) components (not shown) embedded in the fill material 203 within the cavity 204, such as passive components for power delivery (e.g., inductors, capacitors, resistors), active components (e.g., IC dies), etc. In addition, glass substrate 200 may include one or more metal layers (not shown) above and/or below the glass core 202 that collectively form an interconnect. For example, the metal layers may include conductive traces, vias, and/or pads patterned within dielectric layers, which may be electrically coupled to the TGVs 206 and any embedded IC components in the cavity 204. Further, glass substrate 200 may include one or more IC dies (not shown) electrically coupled to the pads on the glass substrate 200.

Various process flows for forming glass substrate 200 are described in further detail throughout the following sections.

### Seedless TGV Process with Mask Over Cavity

In some embodiments, a glass substrate may be formed with a cavity and seedless through-glass vias (TGVs) using a mask over the cavity to avoid electroplating in the cavity (also referred to as plating) when the TGV holes are plated. For example, the glass substrate may be formed by laminating the bottom side or surface of a glass core with a resin copper clad (RCC) laminate, closing off the cavity with a mask to avoid unwanted metal in the cavity when the TGV holes are electroplated, electroplating the TGV holes with copper from the bottom up using a copper foil in the RCC laminate as a seed layer (e.g., instead of lining the TGV sidewalls with a seed layer), and removing the RCC laminate post-plating.

In this manner, by electroplating the TGVs with copper using a removable copper foil on the bottom of the glass substrate instead of a conductive seed layer (e.g., ruthenium or another metal) on the glass sidewalls of the TGVs, the TGVs are seedless, as the TGV sidewalls are not lined with a seed layer. Further, the resulting copper fill fits snug within the TGV holes in the glass core without strong adhesion to the glass sidewalls. As a result, when the copper fill deforms during high-temperature process steps, the stress exerted on the glass sidewalls is reduced significantly due to the relatively weak adhesion between the copper fill and glass sidewalls, which leads to fewer defects (e.g., cracks, chips) in the glass core. This reduction in stress also eliminates the need for a stress absorption liner on the TGV sidewalls, although in some cases, a stress absorption liner may optionally be included to provide additional protection to the glass core.

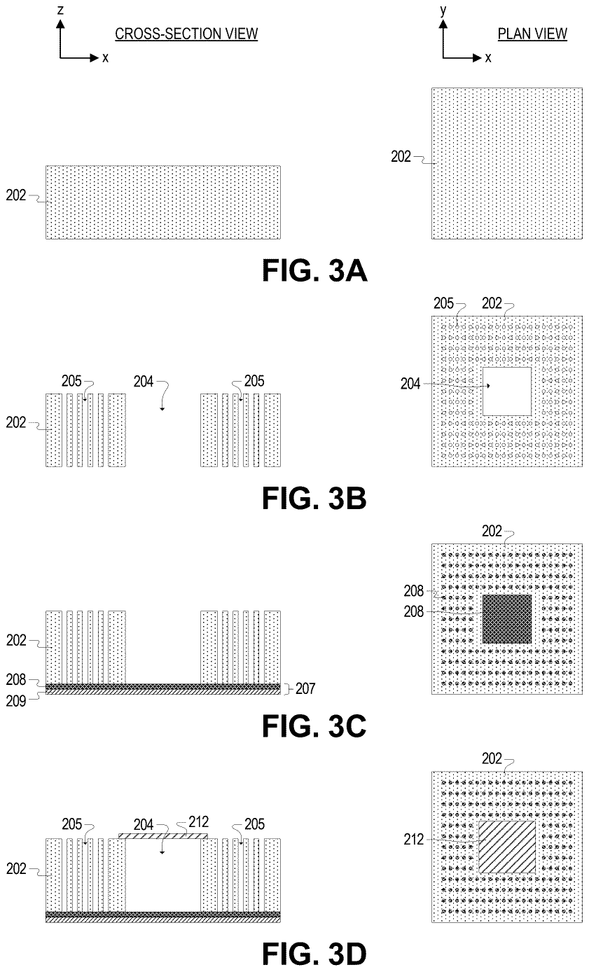

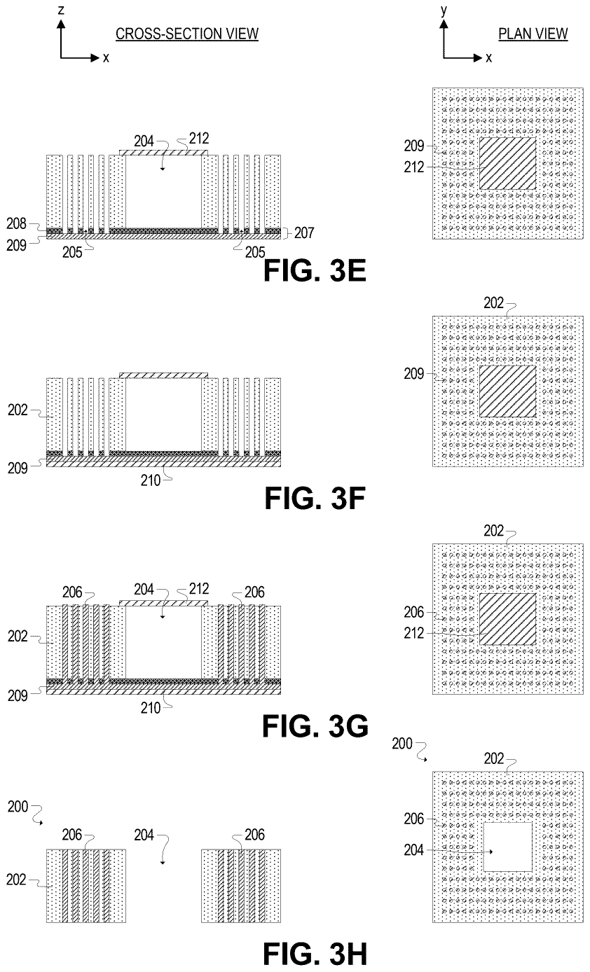

FIGS. 3A-H illustrate an example process flow for forming a glass substrate 200 with a cavity 204 and seedless through-glass vias (TGVs) 206 using a mask 212 over the cavity 204. In the illustrated example, FIGS. 3A-H show cross-section (x-z plane) and plan (x-y plane) views of the substrate after various steps of the process flow. It will be appreciated in light of the present disclosure that the illustrated process flow is only one example methodology for arriving at glass substrate 200.

In FIG. 3A, a glass substrate 202 is received (e.g., a glass panel, subpanel, quarter panel, unit, etc.). The glass substrate 202 is referred to herein as a glass core 202, as it serves as the core of the substrate 200 formed throughout this process flow. The glass core 202 may include any type of glass disclosed herein.

In FIG. 3B, at least one cavity 204 and one or more through-glass via (TGV) holes 205 are formed (e.g., drilled) through the glass core 202. Alternatively, in some embodiments, the glass core 202 may be received with preformed cavities 204 and TGV holes 205 in FIG. 3A.

In some embodiments, a thin stress absorption layer (not shown) may optionally be formed on the glass sidewalls of the TGV holes 205 to absorb stress from deformation of the TGV fill 206 (e.g., copper) during subsequent process steps. For example, the stress absorption layer may be a thin dielectric layer, preferably with a thickness of less than 1 μm, lining the glass sidewalls of the TGV holes 205.

In FIG. 3C, one side of the glass core 202 (e.g., the backside or bottom surface) is laminated with dielectric-conductive cladding 207, which includes a dielectric layer 208 and a conductive layer 209. The dielectric-conductive cladding 207 is laminated over the glass core 202 such that the dielectric layer 208 is between the conductive layer 209 and the glass core 202 to provide adhesion between the conductive layer 209 and glass core 202.

In some embodiments, the dielectric-conductive cladding 207 may be a resin copper clad (RCC) layer or sheet 207, which includes a resin sheet 208 laminated with copper foil 209. Moreover, the glass core 202 may be laminated with the RCC sheet 207 by pressing the RCC sheet 207 onto one side of the glass core 202 and then curing the RCC sheet 207. In other embodiments, the dielectric-conductive cladding 207 may include any other dielectric materials 208 and/or conductive materials 209 (e.g., other metals).

In FIG. 3D, an etch/plating mask 212 is formed over the cavity 204 of the glass core 202. In some embodiments, the mask 212 may include a layer of photoresist (e.g., dry film resist (DFR)) or another adhesive material. Moreover, the mask 212 may be patterned to cover or close off the cavity 204 on the side of the glass core 202 opposite of the cladding 207 (e.g., the frontside or top surface), while leaving the TGV holes 205 uncovered or open. In this manner, the mask 212 protects the cavity 204 from subsequent etching/electroplating steps performed in FIG. 3E and FIG. 3G.

In FIG. 3E, portions of the dielectric cladding layer 208 (e.g., resin sheet) at the bottom of the TGV holes 205 are etched away to expose the conductive cladding layer 209 (e.g., copper foil) through the TGV holes 205. In this manner, the conductive layer 209 can be used as a seed layer to fill the TGV holes 205 with a conductive material (e.g., copper) using electroplating (e.g., in FIG. 3G). Since the cavity 204 will not be electroplated, however, the mask 212 over the cavity 204 prevents portions of the dielectric cladding layer 208 at the bottom of the cavity 204 from being etched.

In FIG. 3F, a plating mask 210 is formed over the conductive cladding layer 209 (e.g., copper foil) on the backside of the glass core 202. In this manner, the plating mask 210 covers the backside of the conductive cladding layer 209, which prevents the conductive cladding layer 209 from growing on the backside when the TGV holes 205 are electroplated with metal (e.g., copper) (e.g., in FIG. 3G). The materials used for plating mask 210 may be similar to those described above for etching/plating mask 212.

In FIG. 3G, an electroplating process is used to fill the TGV holes 205 with a conductive fill material (e.g., copper and/or other metals), thus forming seedless TGVs 206 in the glass core 202. During the electroplating process, the conductive cladding layer 209 serves as the cathode and the conductive fill material 206 serves as the anode, which causes the conductive fill material 206 to grow from the exposed portions of the conductive layer 209 within the TGV holes 205, thus filling or plating the TGV holes 205 from the bottom up.

In this manner, the removable conductive cladding layer 209 serves as the seed layer for the electroplating process, which eliminates the need for a seed layer (e.g., ruthenium or other metals) on the glass sidewalls of the TGVs 206, thus resulting in seedless TGVs 206. As a result, the TGV fill material 206 fits snug within the TGV holes 205 with relatively weak adhesion to the glass sidewalls, which reduces stress to the glass core 202 when the TGV fill material 206 deforms during high-temperature process steps.

Moreover, the mask 212 over the cavity 204 prevents the cavity 204 from being plated or filled with unwanted metal during the electroplating process.

In FIG. 3H, the masks 210, 212 and the cladding 207 (e.g., dielectric/conductive layers 208, 209) are removed from the glass core 202, and both sides of the glass core 202 (e.g., frontside/backside) are grinded to planarize the surface on each side.

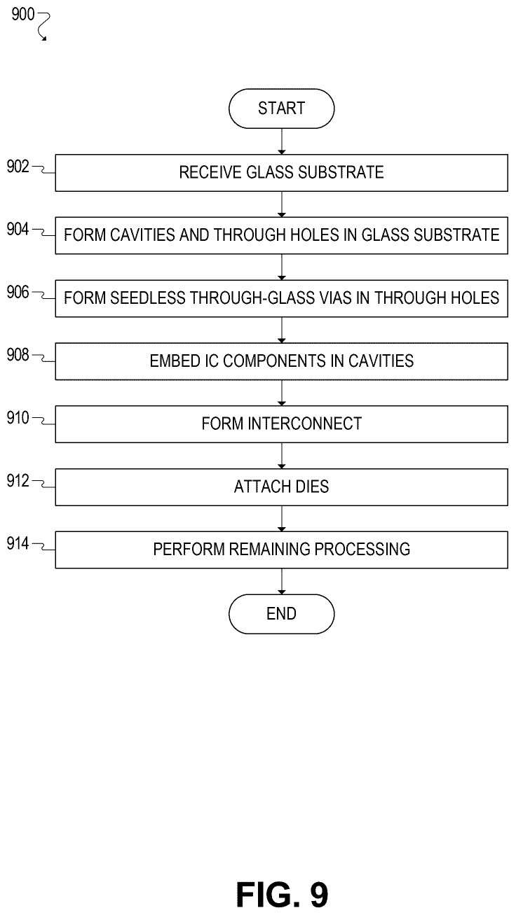

The resulting substrate 200 includes a glass core 202 with a cavity 204 and seedless TGVs 206. At this point, any remaining processing (not shown) may be performed on the resulting glass substrate 200, such as filling the cavity 204 with a cavity fill material 203 (e.g., as shown in FIGS. 2A-B), embedding passive and/or active circuitry within the cavity 204 (e.g., similar to substrates 100a-d of FIGS. 1A-D), interconnect patterning (e.g., forming dielectric buildup layers and conductive layers, patterning the conductive layers into traces, forming vias), die attach, ILD fill/planarization, interconnect bump formation, singulation, etc. (e.g., as described further in connection with process flow 900 of FIG. 9).

### Seedless TGV Process with Removable Cavity Plug

In some embodiments, a glass substrate may be formed with a cavity and seedless through-glass vias (TGVs) using a removable copper cavity plug. In particular, the cavity may be left unmasked or open when the TGV holes are plated, thus filling the cavity with copper (or another metal) to form a copper cavity plug, which may optionally be etched out of the cavity post-plating.

For example, the glass substrate may be formed by laminating the bottom side or surface of a glass core with a resin copper clad (RCC) laminate, electroplating the TGV holes and the cavity with copper from the bottom up using a copper foil in the RCC laminate as a seed layer (e.g., instead of lining the TGV sidewalls and cavity sidewalls with a seed layer), removing the RCC laminate post-plating, and optionally etching out the copper plug from the cavity.

In this manner, the resulting TGVs are seedless (e.g., the TGV sidewalls are not lined with a conductive seed layer), and the copper fill fits snug within the TGV holes in the glass core without strong adhesion to the glass sidewalls, which reduces stress to the glass core when the copper fill deforms during high-temperature process steps. In turn, the reduced stress eliminates the need for a stress absorption liner on the TGV and cavity sidewalls, although one may optionally be included for added protection to the glass core.

Further, the copper cavity plug may either be removed from the cavity or left in the cavity depending on the requirements of the particular application. In some embodiments, for example, the copper plug may be etched out of the cavity to enable other IC components to be embedded in the cavity, such as passive components for power delivery. Alternatively, the copper plug may be left in the cavity and used for another purpose, such as facilitating the transfer of heat through the glass core for thermal management.

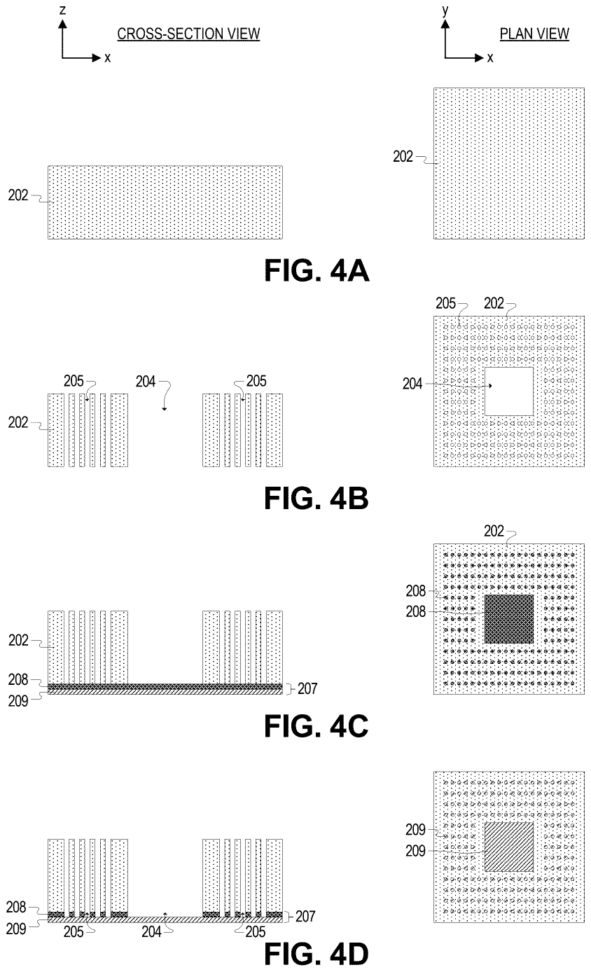

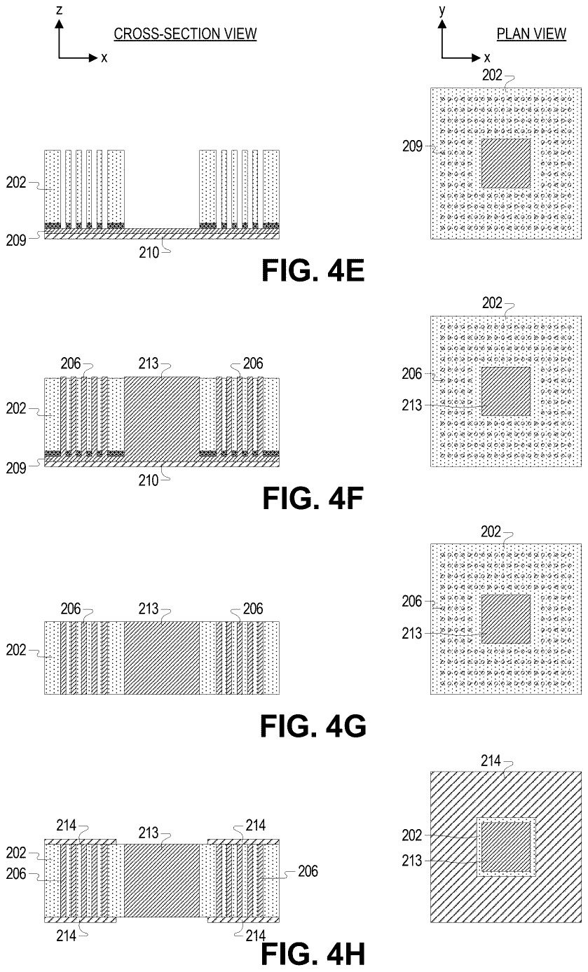

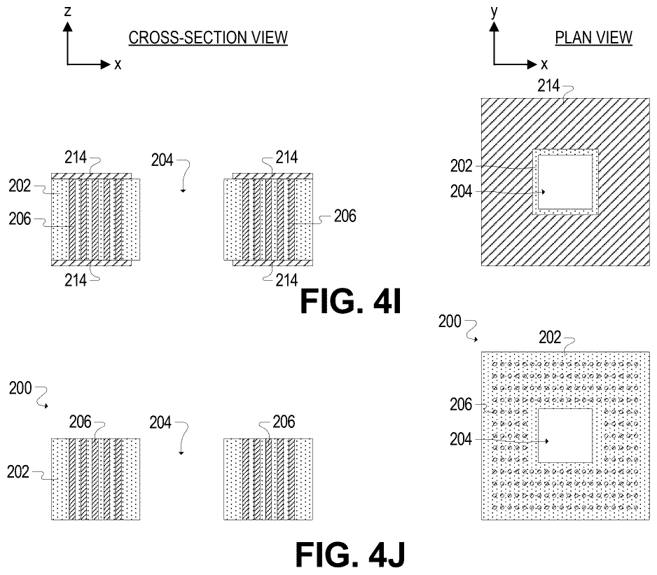

FIGS. 4A-J illustrate an example process flow for forming a glass substrate 200 with a cavity 204 and seedless through-glass vias (TGVs) 206 using a removable copper cavity plug 213. In the illustrated example, FIGS. 4A-J show cross-section (x-z plane) and plan (x-y plane) views of the substrate after various steps of the process flow. It will be appreciated in light of the present disclosure that the illustrated process flow is only one example methodology for arriving at glass substrate 200.

In FIG. 4A, a glass substrate 202 is received (e.g., a glass panel, subpanel, quarter panel, unit, etc.). The glass substrate 202 is referred to herein as a glass core 202, as it serves as the core of the substrate 200 formed throughout this process flow. The glass core 202 may include any type of glass disclosed herein.

In FIG. 4B, at least one cavity 204 and one or more through-glass via (TGV) holes 205 are formed (e.g., drilled) through the glass core 202. Alternatively, in some embodiments, the glass core 202 may be received with preformed cavities 204 and TGV holes 205 in FIG. 4A.

In some embodiments, a thin stress absorption layer (not shown) may optionally be formed on the glass sidewalls of the TGV holes 205 to absorb stress from deformation of the TGV fill 206 (e.g., copper) during subsequent process steps. For example, the stress absorption layer may be a thin dielectric layer, preferably with a thickness of less than 1 μm, lining the glass sidewalls of the TGV holes 205.

In FIG. 4C, one side of the glass core 202 (e.g., the backside or bottom surface) is laminated with dielectric-conductive cladding 207, which includes a dielectric layer 208 and a conductive layer 209. The dielectric-conductive cladding 207 is laminated over the glass core 202 such that the dielectric layer 208 is between the conductive layer 209 and the glass core 202 to provide adhesion between the conductive layer 209 and glass core 202.

In some embodiments, the dielectric-conductive cladding 207 may be a resin copper clad (RCC) layer or sheet 207, which includes a resin sheet 208 laminated with copper foil 209. Moreover, the glass core 202 may be laminated with the RCC sheet 207 by pressing the RCC sheet 207 onto one side of the glass core 202 and then curing the RCC sheet 207. In other embodiments, the dielectric-conductive cladding 207 may include any other dielectric materials 208 and/or conductive materials 209 (e.g., other metals).

In FIG. 4D, portions of the dielectric cladding layer 208 (e.g., resin sheet) at the bottom of the TGV holes 205 and the bottom of the cavity 204 are etched away to expose the conductive cladding layer 209 (e.g., copper foil) through the TGV holes 205 and through the cavity 204. In this manner, the conductive layer 209 can be used as a seed layer to fill the TGV holes 205 and the cavity 205 with a conductive material (e.g., copper) using electroplating (e.g., in FIG. 4F).

In FIG. 4E, a plating mask 210 is formed over the conductive cladding layer 209 (e.g., copper foil) on the backside of the glass core 202. In this manner, the plating mask 210 covers the backside of the conductive cladding layer 209, which prevents the conductive cladding layer 209 from growing on the backside when the TGV holes 205 and the cavity 204 are electroplated with metal (e.g., copper) (e.g., in FIG. 4F).

In FIG. 4F, an electroplating process is used to fill the TGV holes 205 and the cavity 204 with a conductive fill material (e.g., copper and/or other metals), thus forming seedless TGVs 206 and a copper cavity plug 213 in the glass core 202. During the electroplating process, the conductive cladding layer 209 serves as the cathode and the conductive fill material serves as the anode, which causes the conductive fill material to grow from the exposed portions of the conductive layer 209 within the TGV holes 205 and within the cavity 204, thus filling or plating the TGV holes 205 and the cavity 204 from the bottom up. As a result, TGVs 206 and a copper cavity plug 213 are formed in the TGV holes 205 and the cavity 204, respectively.

In this manner, the removable conductive cladding layer 209 serves as the seed layer for the electroplating process, which eliminates the need for a seed layer (e.g., ruthenium or other metals) on the glass sidewalls of the TGVs 206, thus resulting in seedless TGVs 206. As a result, the TGV fill material 206 fits snug within the TGV holes 205 with relatively weak adhesion to the glass sidewalls, which reduces stress to the glass core 202 when the TGV fill material 206 deforms during high-temperature process steps.

Moreover, since the cavity 204 is left unmasked or open during the electroplating process, the cavity 204 is also filled with metal (e.g., copper), thus forming a conductive cavity plug 213 (e.g., filled with a non-magnetic material), which may optionally be removed from the cavity 204 post-plating depending on the requirements of the particular application (as described further with respect to FIG. 4I).

In FIG. 4G, the mask 210 and cladding 207 (e.g., dielectric/conductive layers 208, 209) are removed from the glass core 202, and both sides of the glass core 202 (e.g., frontside/backside) are grinded to planarize the surface on each side.

In FIG. 4H, an etch mask 214 is formed over the TGVs 206 on both sides of the glass core 202, while leaving the cavity plug 213 unmasked or open. In this manner, when the cavity plug 213 is optionally etched away in FIG. 4I, the etch mask 214 covers the TGVs 206 and prevents the TGV fill metal 206 from being etched away. The materials used for mask 214 may be similar to those described above for masks 210, 212.

In FIG. 4I, the cavity plug 213 may optionally be etched out of, and removed from, the cavity 204 depending on the requirements of the particular application. In some embodiments, for example, the conductive plug material 213 (e.g., copper or other metals) may be etched out of the cavity 204 to enable other IC components to be embedded in the cavity 204, such as passive components for power delivery. Moreover, in some cases, after the conductive plug material 213 is etched out of the cavity 204, residue from the conductive plug material 213 may remain in or near the cavity 204, such as a ring of metal (e.g., copper) on the rim of the cavity 204 and/or metal residue on the sidewalls of the cavity 204.

Alternatively, in some embodiments, the conductive plug 213 may be left in the cavity 204 and used for another purpose, such as facilitating the transfer of heat through the glass core 202 for thermal management.

In FIG. 4J, the etch mask 214 is removed from the glass core 202. The resulting substrate 200 includes a glass core 202 with a cavity 204 and seedless TGVs 206. At this point, any remaining processing (not shown) may be performed on the resulting glass substrate 200, such as filling the cavity 204 with a cavity fill material 203 (e.g., as shown in FIGS. 2A-B), embedding passive and/or active circuitry within the cavity 204 (e.g., similar to substrates 100a-d of FIGS. 1A-D), interconnect patterning (e.g., forming dielectric buildup layers and conductive layers, patterning the conductive layers into traces, forming vias), die attach, ILD fill/planarization, interconnect bump formation, singulation, etc. (e.g., as described further in connection with process flow 900 of FIG. 9).

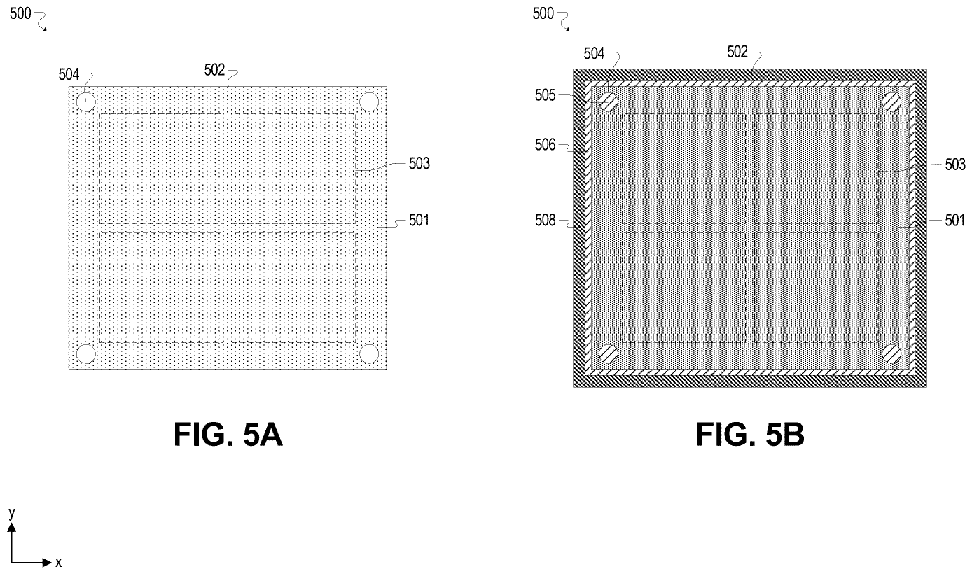

FIGS. 5A-B illustrate an example of a glass substrate 500 with tooling holes 504 processed using the process flow of FIGS. 4A-J. In particular, FIG. 5A shows a plan (x-y plane) view of substrate 500 before processing, and FIG. 5B shows a plan (x-y plane) view of substrate 500 after processing.

In FIG. 5A, before processing, the substrate 500 includes a glass core 502 (e.g., glass panel or subpanel) with fiducial tooling holes 504 in the corners. The substrate 500 is designated with four active areas 503 (e.g., glass quarter panels where processing will be performed), along with a keep out zone (KOZ) 501 along the edges and between the active areas 503. In the illustrated example, the tooling holes 504 are located in the KOZ 501, but in other embodiments, the tooling holes may 504 may be located in the active areas 503 and may remain in some of the singulated units after singulation.

In some embodiments, the fiducial tooling holes 504 may be formed in the glass core 502 when the through-glass via (TGV) holes (not shown) are formed in the glass core 502. Post-TGV plating, however, the fiducial tooling holes 504 may remain unfilled with metal due to their large size. Thus, as shown in FIG. 5B, after processing is complete (e.g., post-lithographic patterning and reconstitution), the tooling holes 504 are filled with material 505 from other processing steps, such as dielectrics (e.g., Ajinomoto Build-up Film (ABF)) from organic and/or prepreg frames 506, 508 formed around the edges of the glass core 502, dielectric buildup layers, etc.

In this manner, the tooling holes 504 are plugged with a non-magnetic material. Moreover, if the tooling holes 504 are in the active areas 503 rather than in the KOZ 501, the plugged tooling holes 504 may remain in some of the singulated units after the substrate 500 is diced.

### Seedless TGV Process with Preferential Cavity Fill

In some embodiments, a glass substrate may be formed with a cavity and seedless through-glass vias (TGVs) using a preferential cavity fill. In particular, the cavity may be preferentially filled with a particular material before the TGV holes are plated, thus preventing the cavity from being filled with unwanted metal (e.g., copper) during the electroplating process.

For example, the glass substrate may be formed by laminating the bottom side or surface of a glass core with a resin copper clad (RCC) laminate, filling the cavity with a dielectric (or any other desired material), electroplating the TGV holes with copper from the bottom up using a copper foil in the RCC laminate as a seed layer (e.g., instead of lining the TGV sidewalls with a seed layer), and removing the RCC laminate post-plating.

In this manner, the resulting TGVs are seedless (e.g., the TGV sidewalls are not lined with a conductive seed layer), and the copper fill fits snug within the TGV holes in the glass core without strong adhesion to the glass sidewalls, which reduces stress to the glass core when the copper fill deforms during high-temperature process steps. In turn, the reduced stress eliminates the need for a stress absorption liner on the TGV and cavity sidewalls, although one may optionally be included for added protection to the glass core. Further, other IC components can subsequently be embedded in the cavity, such as passive components for power delivery (e.g., inductors, capacitors, resistors).

FIGS. 6A-H illustrate an example process flow for forming a glass substrate 200 with a cavity 204 and seedless through-glass vias (TGVs) 206 using a preferential cavity fill. In the illustrated example, FIGS. 6A-H show cross-section (x-z plane) and plan (x-y plane) views of the substrate after various steps of the process flow. It will be appreciated in light of the present disclosure that the illustrated process flow is only one example methodology for arriving at glass substrate 200.

In FIG. 6A, a glass substrate 202 is received (e.g., a glass panel, subpanel, quarter panel, unit, etc.). The glass substrate 202 is referred to herein as a glass core 202, as it serves as the core of the substrate 200 formed throughout this process flow. The glass core 202 may include any type of glass disclosed herein.

In FIG. 6B, at least one cavity 204 and one or more through-glass via (TGV) holes 205 are formed (e.g., drilled) through the glass core 202. Alternatively, in some embodiments, the glass core 202 may be received with preformed cavities 204 and TGV holes 205 in FIG. 6A.

In some embodiments, a thin stress absorption layer (not shown) may optionally be formed on the glass sidewalls of the TGV holes 205 to absorb stress from deformation of the TGV fill 206 (e.g., copper) during subsequent process steps. For example, the stress absorption layer may be a thin dielectric layer, preferably with a thickness of less than 1 μm, lining the glass sidewalls of the TGV holes 205.

In FIG. 6C, one side of the glass core 202 (e.g., the backside or bottom surface) is laminated with dielectric-conductive cladding 207, which includes a dielectric layer 208 and a conductive layer 209. The dielectric-conductive cladding 207 is laminated over the glass core 202 such that the dielectric layer 208 is between the conductive layer 209 and the glass core 202 to provide adhesion between the conductive layer 209 and glass core 202.

In some embodiments, the dielectric-conductive cladding 207 may be a resin copper clad (RCC) layer or sheet 207, which includes a resin sheet 208 laminated with copper foil 209. Moreover, the glass core 202 may be laminated with the RCC sheet 207 by pressing the RCC sheet 207 onto one side of the glass core 202 and then curing the RCC sheet 207. In other embodiments, the dielectric-conductive cladding 207 may include any other dielectric materials 208 and/or conductive materials 209 (e.g., other metals).

In FIG. 6D, a fill mask 216 is formed over the TGV holes 205 on the frontside of the glass core 202, and a plating mask 210 is formed over the conductive cladding layer 209 (e.g., copper foil) on the backside of the glass core 202. In this manner, the fill mask 216 covers or closes off the TGV holes 205 on the frontside of the glass core 202, while leaving the cavity 204 uncovered or open, thus preventing the TGV holes 205 from being filled when the cavity 204 is filled in FIG. 6E. Moreover, the plating mask 210 covers the backside of the conductive cladding layer 209, which prevents the conductive cladding layer 209 from growing on the backside when the TGV holes 205 are electroplated with metal (e.g., copper) (e.g., in FIG. 6G). The materials used for masks 210, 216 may be similar to those described above for mask 212.

In FIG. 6E, the cavity 204 is filled with a cavity fill material 203, such as a dielectric or any other desired material. Since the TGV holes 205 are covered by a mask 216, however, the TGV holes 205 are not filled when the cavity 204 is filled.

In FIG. 6F, portions of the dielectric cladding layer 208 (e.g., resin sheet) at the bottom of the TGV holes 205 are etched away to expose the conductive cladding layer 209 (e.g., copper foil) through the TGV holes 205. In this manner, the conductive layer 209 can be used as a seed layer to fill the TGV holes 205 with a conductive material (e.g., copper) using electroplating (e.g., in FIG. 6G).

In FIG. 6G, an electroplating process is used to fill the TGV holes 205 with a conductive fill material (e.g., copper and/or other metals), thus forming seedless TGVs 206 in the glass core 202. During the electroplating process, the conductive cladding layer 209 serves as the cathode and the conductive fill material 206 serves as the anode, which causes the conductive fill material 206 to grow from the exposed portions of the conductive layer 209 within the TGV holes 205, thus filling or plating the TGV holes 205 from the bottom up.

In this manner, the removable conductive cladding layer 209 serves as the seed layer for the electroplating process, which eliminates the need for a seed layer (e.g., ruthenium or other metals) on the glass sidewalls of the TGVs 206, thus resulting in seedless TGVs 206. As a result, the TGV fill material 206 fits snug within the TGV holes 205 with relatively weak adhesion to the glass sidewalls, which reduces stress to the glass core 202 when the TGV fill material 206 deforms during high-temperature process steps.

Moreover, since the cavity 204 was preferentially filled before plating the TGV holes 205, the cavity fill material 203 prevents the cavity 204 from being plated or filled with unwanted metal during the electroplating process.

In FIG. 6H, the plating mask 210 and the cladding 207 (e.g., dielectric/conductive layers 208, 209) are removed from the glass core 202, and both sides of the glass core 202 (e.g., frontside/backside) are grinded to planarize the surface on each side.

The resulting substrate 200 includes a glass core 202 with a filled cavity 203 and seedless TGVs 206. Moreover, since the cavity 204 was preferentially filled with a dielectric fill material 203, the cavity fill layer 203 will be distinct from any dielectric buildup layers subsequently formed above and below the glass core (e.g., as shown in substrate 100d of FIG. 1D).

At this point, any remaining processing (not shown) may be performed on the resulting glass substrate 200, such as embedding passive and/or active circuitry within the cavity 204 (e.g., similar to substrates 100a-d of FIGS. 1A-D), interconnect patterning (e.g., forming dielectric buildup layers and conductive layers, patterning the conductive layers into traces, forming vias), die attach, ILD fill/planarization, interconnect bump formation, singulation, etc. (e.g., as described further in connection with process flow 900 of FIG. 9).

### Example Embodiments

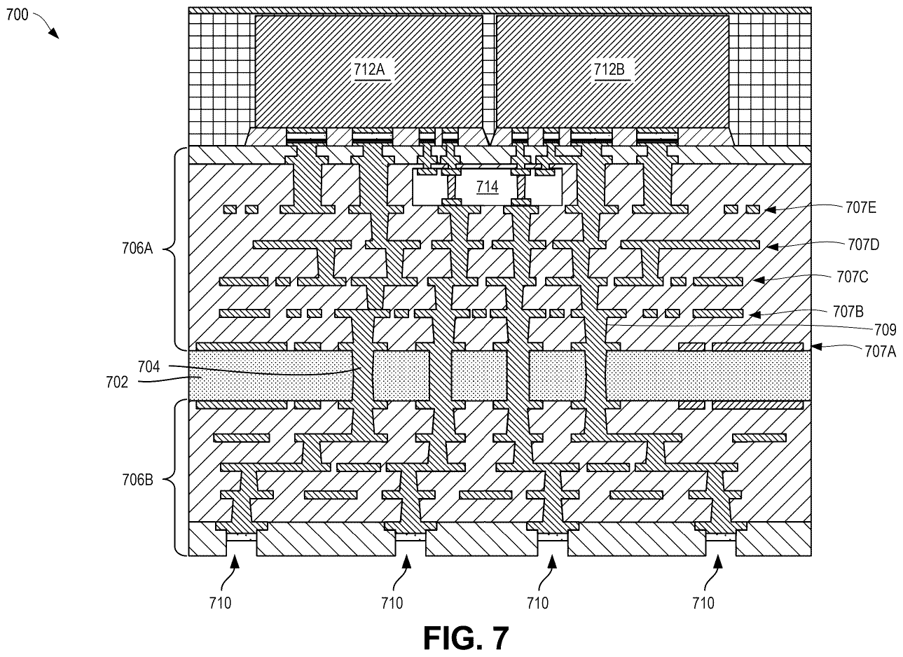

FIG. 7 illustrates an example of a multi-die integrated circuit (IC) package 700. In some embodiments, the core layer 702 of IC package 700 may be implemented using a glass substrate with one or more seedless TGVs and/or cavities according to any of the embodiments described herein (e.g., substrates 100a-d, 200, 500).

The package 700 includes a core layer 702 and vias 704 through the core layer 702 (e.g., extending between the top and bottom surfaces of the core layer 702). Buildup layers 706 are formed on the top and bottom sides or surfaces of the core layer 702, with buildup layers 706A on the top side of the core layer 702 and the buildup layers 706B on bottom side of the core layer 702. The buildup layers 706 include metal traces in metallization layers (e.g., 707A-E) and pillars/vias (e.g., 709) between the metallization layers as shown to electrically couple components on the top of the package 700 with the pads 710 at the bottom of the package. For example, the layers 706 may provide connections between the integrated circuit (IC) dies 712 coupled to the top side of the package to a circuit board (e.g., a motherboard, main board, etc.) via the pads 710 at the bottom of the package. The package 700 also includes an interconnect bridge circuitry component 714 located in the buildup layers 706A that electrically couples the first IC die 712A with the second IC die 712B. The interconnect bridge circuitry component 714 may include passive and/or active components to interconnect the IC dies 712. As shown, the interconnect bridge circuitry component 714 includes through silicon vias to connect a top side of the component 714 with a bottom side. The interconnect bridge circuitry component 714 may be an Intel® embedded multi-die interconnect bridge with through silicon vias (EMIB-T) in certain embodiments.

The IC dies 712A, B may include any type or combination of integrated circuit, including, without limitation, processing circuitry, communication circuitry, memory circuitry, and/or storage circuitry. In some embodiments, for example, the IC dies 712A, B may include one or more systems-on-a-chip (SoCs), processing units (e.g., central processing units (CPUs), graphics processing units (GPUs), vision processing units (VPUs), neural processing units (NPUs), XPUs, microprocessors, microcontrollers), field-programmable gate arrays (FPGAs), application-specific integrated circuits (ASICs), network interface controllers (NICs), persistent storage devices, input/output (I/O) devices and controllers, memory devices and controllers, etc.

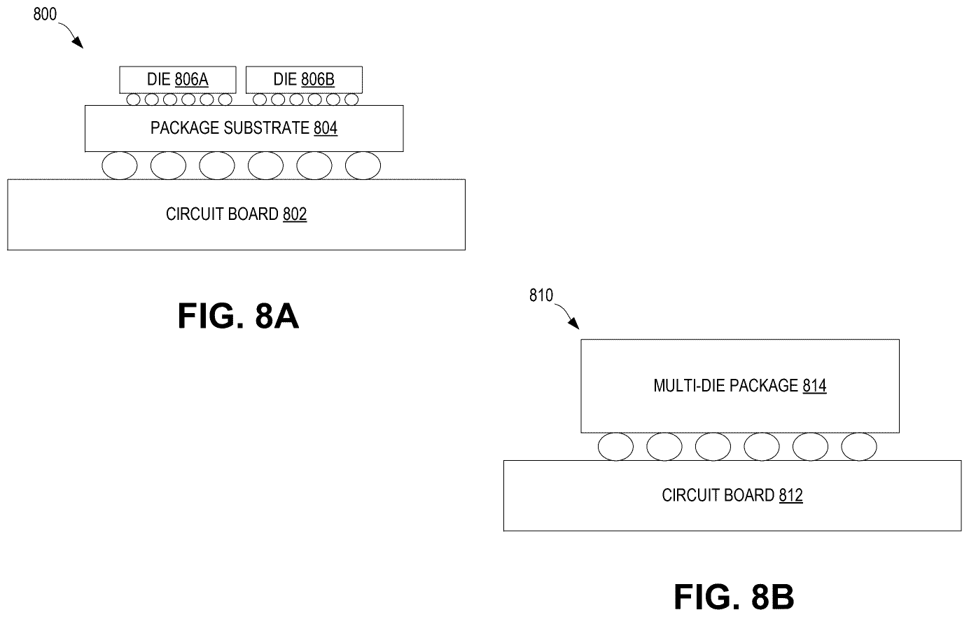

FIGS. 8A-B illustrate example systems 800, 810 that may incorporate the embodiments described herein. In some embodiments, for example, the package substrate 804 of system 800 and the multi-die package 814 of system 810 may include or may be implemented using a glass substrate with one or more seedless TGVs and/or cavities (e.g., substrates 100a-d, 200, 500).

In FIG. 8A, example system 800 includes a circuit board 802, which may be implemented as a motherboard or main board of a computer system in some embodiments. The example system 800 also includes a package substrate 804 with integrated circuit dies 806A, 806B attached to the package substrate 804. The dies 806 may be packaged or unpackaged integrated circuit products that include one or more integrated circuit dies (e.g., dies 1102, dies 712A,B) and/or one or more other suitable components. The respective dies 806 can comprise one or more computing system components, such as one or more processor units (e.g., system-on-a-chip (SoC), processor core, central processing unit (CPU), graphics processing unit (GPU), XPU, accelerator, chipset processor), I/O controller, memory, or network interface controller. In some embodiments, the dies 806 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the dies 806 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” The package substrate 804 may provide electrical connections between the die 806 and the circuit board 802 and may include an embedded interconnect bridge circuitry die as described above.

In FIG. 8B, example system 810 also includes a circuit board 812, which may be implemented as a motherboard or main board of a computer system in some embodiments. The system 810 also includes a multi-die package 814, which includes multiple integrated circuits/dies (e.g., 806), and interconnections between the dies in one or more metallization layers. The multi-die package 814 may include, for example, one or more silicon interposers, one or more silicon bridges embedded in the package substrate. For example, the package 814 may include an embedded interconnect bridge circuitry die (e.g., an Intel® embedded multi-die interconnect bridge (EMIB) as described above.

The main circuit board 802, 812 of systems 800, 810 may provide electrical connections to other components of a computer system, e.g., memory, storage, network interfaces, peripheral devices, power supplies, etc. The main circuit board 802, 812 may include one or more traces and circuit components to provide interconnects between such computer system components.

In some embodiments, systems 800, 810 may be included in an electronic device, including, without limitation, a cell phone, a wearable device, a computer (e.g., desktop computer, laptop computer, server), a camera, a video playback device, a video game console, a display device, a vehicle control unit, an appliance, etc.

FIG. 9 illustrates an example process flow 900 for packaging integrated circuits on a glass substrate core with one or more cavities and seedless through-glass vias (TGVs). In some embodiments, for example, the illustrated process flow may be used to form one or more integrated circuit (IC) packages (e.g., IC package 700) on any of the glass substrates described herein (e.g., substrates 100a-d, 200, 500). It will be appreciated in light of the present disclosure that the illustrated process flow is only one example methodology for arriving at the example substrates, devices, and systems shown and described throughout this disclosure.

The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 902 by receiving a glass substrate (e.g., glass panel, quarter panel, or unit). The glass substrate may include any type of glass disclosed herein. The glass substrate serves as the core of a package substrate formed throughout the remaining blocks of the process flow.

The flowchart then proceeds to block 904 to form one or more cavities and one or more through holes in the glass substrate (e.g., by drilling or etching holes through the glass substrate). Alternatively, in some embodiments, the glass substrate may be received with preformed cavities and/or through holes.

The flowchart then proceeds to block 906 to form seedless through-glass vias (TGVs) in the through holes. In some embodiments, for example, the seedless TGVs may be formed using any of the process flows disclosed herein (e.g., the process flows of FIG. 3, FIG. 4, or FIG. 6).

The flowchart then proceeds to block 908 to embed integrated circuit (IC) components in the cavities. In some embodiments, for example, the IC components may be monolithically fabricated within the cavities, or alternatively, the IC components may be separately fabricated and then integrated within the cavities. In various embodiments, the cavity IC components may include passive circuitry (e.g., power delivery circuitry such as inductors, capacitors, resistors, vias) and/or active circuitry (e.g., embedded dies).

The flowchart then proceeds to block 910 to form an interconnect on the glass substrate. For example, one or more interleaving dielectric layers and conductive (e.g., metal) layers may be formed above and/or below the glass substrate, such that the conductive layers are separated by dielectric layers. The conductive layers may then be patterned (e.g., etched) into conductive traces, and vias may be formed (e.g., etched and filled) through the intervening dielectric layers to electrically couple the traces in different conductive layers. Moreover, the conductive traces and vias may be electrically coupled to the TGVs and the cavity IC components. Further, conductive contacts (e.g., metal pads) electrically coupled to the vias and traces may be formed (e.g., on the surface, in a cavity, etc.) to enable other components to be electrically coupled to the package, such as the IC dies that are attached at block 912. In some embodiments, one or more interconnect bridges may also be embedded in the package (e.g., within the dielectric layers) to provide an interconnect between certain components, such as the IC dies that are attached at block 912. The conductive traces, vias, conductive contacts, and/or interconnect bridges collectively form an interconnect for the respective components that will be included in the package.

The flowchart then proceeds to block 912 to attach one or more integrated circuit (IC) dies to the package. In particular, the IC dies may be assembled on the package such that conductive contacts (e.g., microbumps, pads) on the IC dies are electrically coupled to conductive contacts (e.g., pads) on the package, thus providing a first level interconnect (FLI) between the respective IC dies and the package.

In various embodiments, for example, the IC dies may be attached to the top or bottom sides or surfaces of the package, or alternatively, the IC dies may be embedded in the package (e.g., within cavities in the glass substrate or within dielectric layers on the glass substrate). Moreover, the IC dies may be attached to the package using any suitable technique, including hybrid bonding the dies to the substrate (e.g., dielectric-to-dielectric and metal-to-metal bonds between dielectric layers with recessed metal (e.g., copper) pads on the respective dies and substrate), flip-chip bonding the dies to the substrate using microbumps (e.g., bonding microbumps on the face of the respective dies to corresponding pads on the substrate), etc.

The flowchart then proceeds to block 914 to perform any remaining processing, such as inter-layer dielectric (ILD) filling, planarization, interconnect bump formation, etc. For example, conductive contacts (e.g., solder balls/bumps) may be formed on one or more surfaces of the substrate to provide a second level interconnect (SLI) to another component, such as another IC substrate or package, a printed circuit board (PCB), etc.

In panel-level or wafer-level process flows, the resulting panel or wafer may be diced to singulate the IC packages on the panel or wafer. The singulated IC packages may then be attached to, or incorporated in, another IC substrate or package, a PCB, an electronic device or system (e.g., systems 800, 810, IC device 1200, electronic device 1300), etc.

At this point, the flowchart may be complete. In some embodiments, however, the flowchart may restart and/or certain blocks may be repeated. For example, in some embodiments, the flowchart may restart at block 902 to continue packaging integrated circuits on a glass substrate.

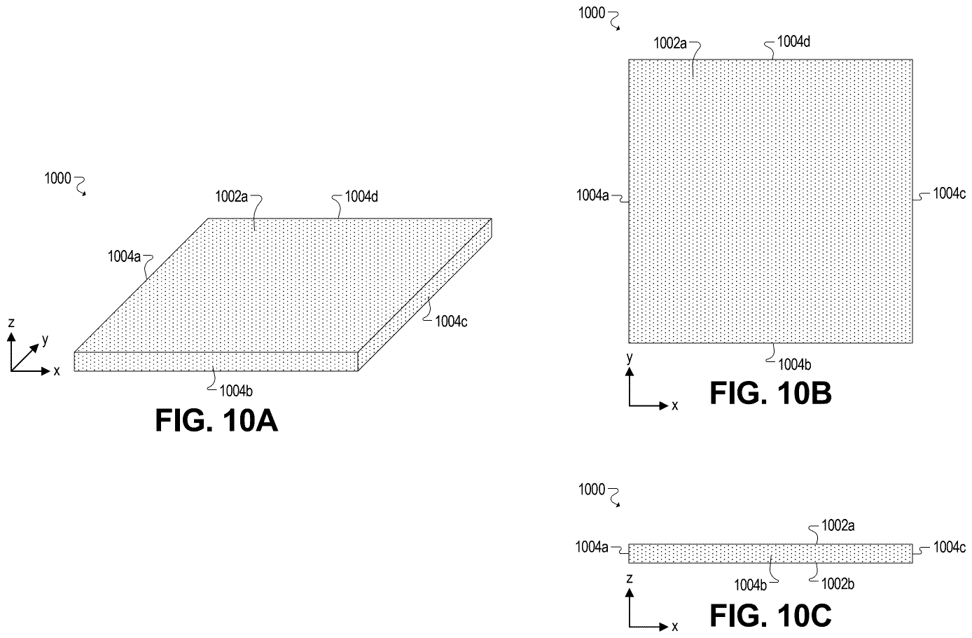

FIGS. 10A-C illustrate an example of a glass substrate 1000. In particular, perspective, plan, and cross-section views of the glass substrate 1000 are shown in FIGS. 10A, 10B, and 10C, respectively. In some embodiments, the glass substrate 1000 may be included in the substrates (e.g., substrates 100a-d, 200, 500) and/or integrated circuit devices and systems (e.g., IC package 700, systems 800, 810, IC device 1200, electronic device 1300) described throughout this disclosure.

In the illustrated embodiment, the glass substrate 1000 includes top and bottom surfaces/sides 1002a-b and four sides/edges 1004a-d. In various embodiments, the glass substrate 1000 may be a glass panel, subpanel, quarter panel, unit, or any other size or type of glass structure.

As used herein, the term “glass,” when referring to a glass structure such as a glass substrate 1000 (e.g., glass panel, subpanel, quarter panel, unit, core, substrate, etc.), may refer to one or more layers of glass (e.g., a glass layer), a portion of a glass layer, or other structure of any glass material. In particular, the glass may be bulk glass or a solid volume/layer of glass, as opposed to, for example, materials that may include particles of glass, such as glass fiber reinforced polymers (e.g., substrates/boards constructed of glass fibers and an epoxy binder). Such bulk/solid glass materials are typically non-crystalline, often transparent, amorphous solids. In some embodiments, the glass may be an amorphous solid glass layer.

A glass substrate 1000 may be made of, or may include, any suitable glass material, including, without limitation, quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass.

In some embodiments, the glass substrate 1000 may be made of a material that includes elements such as silicon (Si) and oxygen (O), as well as any one or more of aluminum (Al), boron (B), magnesium (Mg), calcium (Ca), barium (Ba), tin (Sn), sodium (Na), potassium (K), strontium (Sr), phosphorus (P), zirconium (Zr), lithium (Li), titanium (Ti), or zinc (Zn).

In some embodiments, the glass substrate 1000 may include a material, e.g., any of the materials described above, with a weight percentage of silicon being at least about 0.5%, e.g., between about 0.5% and 50%, between about 1% and 48%, or at least about 23%. For example, if the glass material is fused silica, the weight percentage of silicon may be about 47%. In some embodiments, the glass substrate 1000 may include a material having at least 23% silicon and/or at least 26% oxygen by weight, and, in some further embodiments, the glass substrate 1000 may further include at least 5% aluminum by weight.

In some embodiments, the glass substrate 1000 may include any of the materials described above and may further include one or more additives, such as aluminum oxide (Al2O3), boron trioxide (B2O3), magnesium oxide (MgO), calcium oxide (CaO), strontium oxide (SrO), barium oxide (BaO), tin(IV) oxide (SnO2), sodium oxide (Na2O), potassium oxide (K2O), diphosphorus trioxide (P2O3), zirconium dioxide (ZrO2), lithium oxide (Li2O), titanium (Ti), and zinc (Zn).

In some embodiments, the glass substrate 1000 may be a layer of glass that does not include an organic adhesive or an organic material. The glass substrate 1000 may be distinguished from, for example, a “prepreg” or “RF4” core of a PCB substrate which typically includes glass fibers embedded in a resinous organic material such as an epoxy. In such traditional cores/substrates including glass fibers and epoxy, the diameter of the glass fibers is generally in the range of 5 micrometers (microns or μm) to 200 μm.

In contrast, in some embodiments, the dimensions of the glass substrate 1000 (e.g., a glass core, glass layer, or overall glass substrate) may be in a range of about 10 millimeters (mm) per side to 250 mm per side (e.g., 10×10 mm to 250×250 mm). Further, in some embodiments, the dimensions of the glass substrate 1000 may be up to 600 mm on a side (e.g., a glass panel with dimensions of 510x 515 mm or 600×600 mm).

In some embodiments, a cross-section of the glass substrate 1000 in an x-z plane, y-z plane, and/or x-y plane of an example coordinate system, may be substantially rectangular. In at least some such embodiments, in a top-down or plan view of the glass substrate 1000 (e.g., the x-y plane), the glass substrate 1000 may comprise a solid layer of glass substantially rectangular in shape and may have a first length in a range of 10 mm to 250 mm, and a second length in a range of 10 mm to 250 mm, the first length perpendicular to the second length.

In some embodiments, the glass substrate 1000 may be a layer of glass comprising a rectangular prism volume. In some such embodiments, the rectangular prism volume may have a first side and a second side perpendicular to the first side, the first side having a length in a range of 10 mm to 250 mm and the second side having a length in a range of 10 mm to 250 mm.

In some embodiments, the glass substrate 1000 may have a thickness (e.g., a dimension measured along the z axis) in a range of about 50 μm to 1.4 mm. In some embodiments, for example, the glass substrate 1000 may be a glass core substrate with a thickness of about 50 μm to 1.4 mm.

In some embodiments, the glass substrate 1000 may be a layer of glass having a thickness in a range of 50 μm to 1.4 mm, a first length in a range of 10 mm to 250 mm, and a second length in a range of 10 mm to 250 mm, the first length perpendicular to the second length.

In some embodiments, the glass substrate 1000 may be a multi-layer glass substrate (e.g., a coreless substrate), where a glass layer of the substrate 1000 has a thickness in a range of about 25 μm to 50 μm.

In some embodiments, the glass substrate 1000 may comprise a rectangular prism volume with sections (e.g., vias) removed and filled with at least one other material (e.g., metal). For example, the glass substrate 1000 may include a via extending from a first surface/side 1002a,b of the rectangular prism volume to a second surface/side 1002a,b of the rectangular prism volume, where the via includes a metal, thus forming a through-glass via (TGV) through the glass substrate 1000.

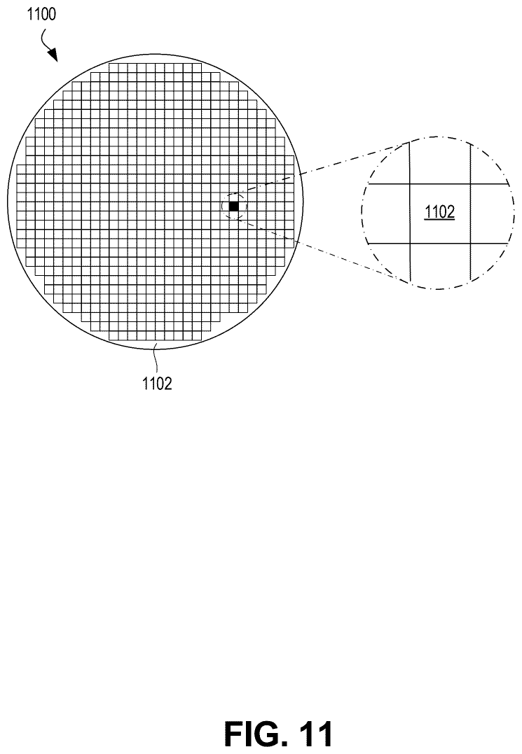

FIG. 11 is a top view of a wafer 1100 and dies 1102 that may be included in, or may include, any of the embodiments disclosed herein. In some embodiments, for example, the respective dies 1102 may be included in an integrated circuit device or system (e.g., IC package 700, systems 800, 810, IC device 1200) implemented using a glass substrate with seedless TGVs according to any of the embodiments described throughout this disclosure (e.g., substrates 100a-d, 200, 500).

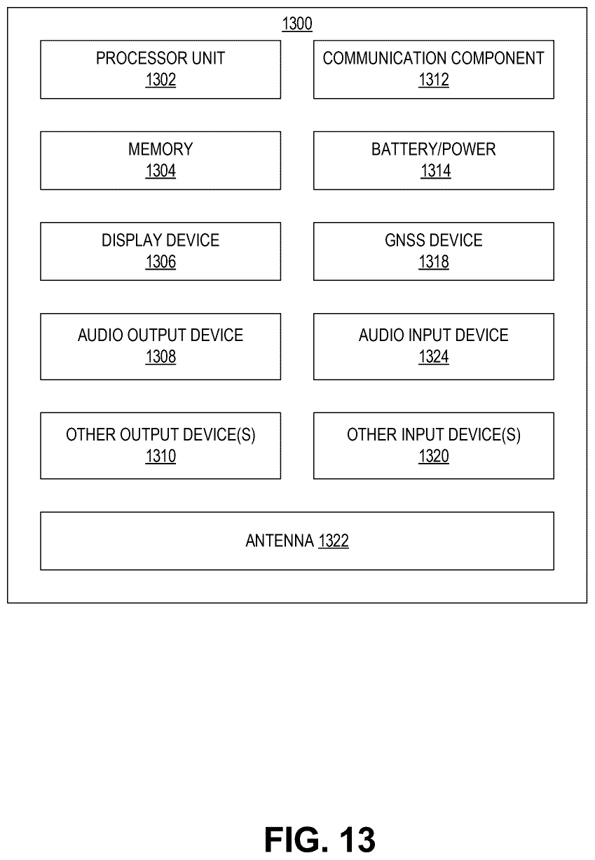

The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may be any of the dies disclosed herein. The die 1102 may include one or more transistors, supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1302 of FIG. 13) or other logic that is configured to store information in the memory devices or execute instructions stored in the memory array. Various ones of the microelectronic assemblies disclosed herein may be manufactured using a die-to-wafer assembly technique in which some dies are attached to a wafer 1100 that include others of the dies, and the wafer 1100 is subsequently singulated.

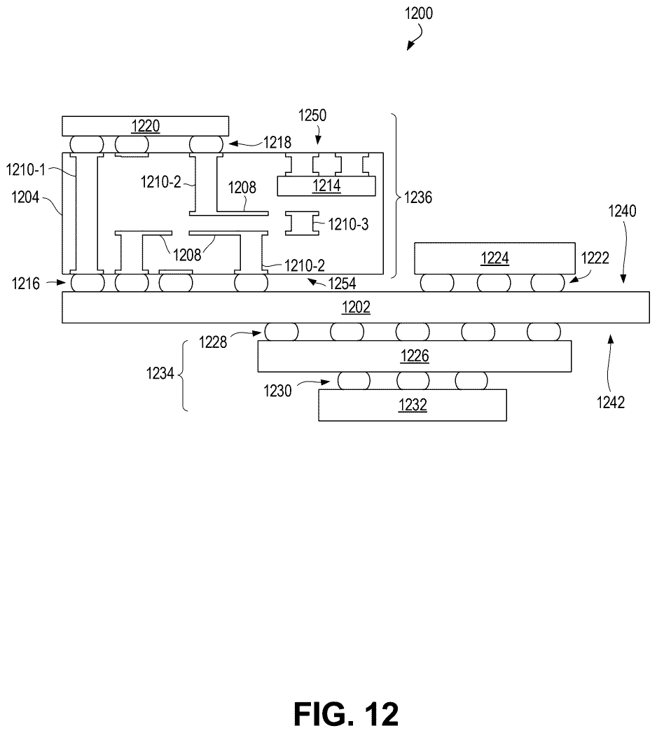

FIG. 12 is a cross-sectional side view of an integrated circuit device assembly 1200 that may include any of the embodiments disclosed herein. In some embodiments, for example, the circuit board 1202, IC components 1220, 1224, 1226, 1232, interposers 1204, 1206, and/or embedded devices 1214 of the integrated circuit device assembly 1200 may include, or may be formed on, a glass substrate with one or more cavities and/or seedless TGVs according to any of the embodiments described throughout this disclosure (e.g., substrates 100a-d, 200, 500).

In some embodiments, the integrated circuit device assembly 1200 may be a microelectronic assembly. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the microelectronic assemblies disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit product that includes one or more integrated circuit dies (e.g., the die 1102 of FIG. 11) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the embodiments disclosed herein. For example, any suitable ones of the components of the electrical device 1300 may include one or more of the glass substrates (e.g., substrates 100a-d, 200, 500), integrated circuit device assemblies 1200, integrated circuit components 1220, or integrated circuit dies 1102 disclosed herein.

A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1(L1), Level 2(L2), Level 3(L3), Level 4(L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include other output device(s) 1310 (or corresponding interface circuitry, as discussed above). Examples of the other output device(s) 1310 may include an audio codec, a video codec, a printer, a wired or wireless transmitter for providing information to other devices, or an additional storage device.

The electrical device 1300 may include other input device(s) 1320 (or corresponding interface circuitry, as discussed above). Examples of the other input device(s) 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/-10% of a target value (unless otherwise specified). Similarly, terms describing spatial relationships, such as “perpendicular,” “orthogonal,” or “coplanar,” may refer to being substantially within the described spatial relationships (e.g., within +/-10 degrees of orthogonality).

Certain terminology may also be used in the foregoing description for the purpose of reference only, and thus are not intended to be limiting. For example, terms such as “upper,” “lower,” “above,” “below,” “over,” “under,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” may correspond to orthogonal planes within a cartesian coordinate system. For example, cross-sectional and profile views may be taken in the x-z plane, and plan views may be taken in the x-y plane. Where appropriate, drawings are labeled with axes to indicate the orientation of the figure.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material (e.g., organic materials, glass). The core may have vias extending from one side to the other, allowing circuitry on one side of the core to be coupled directly to circuitry on the opposite side of the core. The core may also serve as a platform for building up layers of conductors and dielectric materials.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform. A substrate may include dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a substrate, comprising: a glass layer comprising a rectangular prism volume; a cavity in the glass layer; and one or more vias extending between top and bottom surfaces of the glass layer, wherein the vias are filled with a first conductive material, and wherein sidewalls of the vias are not lined with a second conductive material.

Example 2 includes the substrate of Example 1, wherein the first conductive material comprises at least one of copper, tungsten, aluminum, gold, nickel, platinum, or molybdenum.

Example 3 includes the substrate of Example 1, wherein the first conductive material comprises copper.

Example 4 includes the substrate of any of Examples 1-3, wherein the second conductive material comprises ruthenium or copper.

Example 5 includes the substrate of any of Examples 1-4, wherein the first conductive material is a conductive fill material, and wherein the second conductive material is a conductive seed material.

Example 6 includes the substrate of any of Examples 1-5, further comprising passive circuitry at least partially within the cavity, wherein the passive circuitry is to be electrically coupled to a power supply.

Example 7 includes the substrate of Example 6, wherein the passive circuitry comprises at least one inductor, capacitor, or resistor.

Example 8 includes the substrate of any of Examples 6-7, further comprising a first dielectric layer, a second dielectric layer, and a third dielectric layer, wherein the first dielectric layer is above the glass layer, wherein the second dielectric layer is below the glass layer, wherein the third dielectric layer is within the cavity, and wherein the passive circuitry is at least partially within the third dielectric layer.

Example 9 includes the substrate of any of Examples 1-8, wherein: the cavity is filled with the first conductive material; or the cavity comprises residue from the first conductive material.

Example 10 includes the substrate of any of Examples 1-9, further comprising one or more tooling holes in the glass layer, wherein the tooling holes are filled with a non-magnetic material.

Example 11 includes the substrate of any of Examples 1-10, wherein the vias are seedless through-glass vias.

Example 12 includes the substrate of any of Examples 1-11, wherein adhesion between the first conductive material and the sidewalls of the vias is weak.

Example 13 includes the substrate of any of Examples 1-12, wherein the sidewalls of the vias are lined with a dielectric material.

Example 14 includes the substrate of Example 13, wherein the dielectric material has a thickness of less than 1 micrometer.

Example 15 includes an electronic device, comprising: a substrate comprising a glass core, wherein the glass core is not comprised of an organic adhesive or an organic material, wherein the glass core comprises a cavity and one or more through-glass vias (TGVs), wherein the TGVs comprise a conductive fill layer, and wherein the TGVs do not comprise a conductive liner between the conductive fill layer and interior walls of the TGVs; and an integrated circuit (IC) die electrically coupled to the substrate.

Example 16 includes the electronic device of Example 15, wherein the conductive fill layer comprises copper.

Example 17 includes the electronic device of any of Examples 15-16, wherein the substrate further comprises passive circuitry at least partially within the cavity, wherein the passive circuitry is electrically coupled to the IC die, and wherein power is to be delivered to the IC die through the passive circuitry.

Example 18 includes the electronic device of Example 17, wherein the passive circuitry comprises at least one of an inductor, a capacitor, or a resistor.

Example 19 includes the electronic device of any of Examples 17-18, wherein the substrate further comprises a first dielectric layer, a second dielectric layer, and a third dielectric layer, wherein the first dielectric layer is above the glass core, wherein the second dielectric layer is below the glass core, wherein the third dielectric layer is within the cavity, and wherein the passive circuitry is at least partially within the third dielectric layer.

Example 20 includes the electronic device of any of Examples 15-19, wherein the conductive fill layer has weak adhesion to the interior walls of the TGVs.

Example 21 includes the electronic device of any of Examples 15-20, wherein the TGVs extend between top and bottom surfaces of the glass core.

Example 22 includes the electronic device of any of Examples 15-21, wherein the TGVs are seedless TGVs.

Example 23 includes the electronic device of any of Examples 15-22, wherein the TGVs further comprise a dielectric liner between the conductive fill layer and the interior walls of the TGVs.

Example 24 includes the electronic device of any of Examples 15-23, wherein the substrate further comprises: a plurality of dielectric layers above and below the glass core; a plurality of conductive traces and vias within the dielectric layers; and a plurality of conductive contacts on one or more surfaces of the substrate.

Example 25 includes the electronic device of any of Examples 15-24, further comprising: a circuit board; and an IC package electrically coupled to the circuit board, wherein the IC package comprises the substrate and the IC die.

Example 26 includes the electronic device of any of Examples 15-25, wherein the IC die comprises processing circuitry, communication circuitry, or memory circuitry.

Example 27 includes a method, comprising: receiving a glass substrate, wherein the glass substrate includes one or more through-glass via (TGV) holes and one or more cavities; forming a conductive layer over a first side of the glass substrate; forming one or more TGVs in the glass substrate, wherein the TGV holes are filled with a conductive material using an electroplating process, wherein the conductive layer is a cathode and the conductive material is an anode in the electroplating process; and removing the conductive layer from the glass substrate.

Example 28 includes the method of Example 27, wherein: forming the conductive layer over the first side of the glass substrate comprises: forming a dielectric layer and the conductive layer over the first side of the glass substrate, wherein the dielectric layer is between the conductive layer and the glass substrate; and removing the conductive layer from the glass substrate comprises: removing the dielectric layer and the conductive layer from the glass substrate.

Example 29 includes the method of Example 28, wherein forming the dielectric layer and the conductive layer over the first side of the glass substrate comprises: forming a resin copper clad (RCC) layer over the first side of the glass substrate, wherein the RCC layer comprises the dielectric layer and the conductive layer, wherein the dielectric layer comprises resin, and wherein the conductive layer comprises copper.

Example 30 includes the method of any of Examples 28-29, wherein forming the one or more TGVs in the glass substrate comprises: forming a mask over a second side of the glass substrate, wherein the mask covers the cavities; etching portions of the dielectric layer to expose the conductive layer through the TGV holes; and filling the TGV holes with the conductive material using the electroplating process.

Example 31 includes the method of any of Examples 28-29, wherein forming the one or more TGVs in the glass substrate comprises: etching portions of the dielectric layer to expose the conductive layer through the TGV holes and the cavities; and filling the TGV holes and the cavities with the conductive material using the electroplating process.

Example 32 includes the method of Example 31, wherein forming the one or more TGVs in the glass substrate further comprises: etching away the conductive material in the cavities.

Example 33 includes the method of any of Examples 27-32, further comprising, before forming the one or more TGVs in the glass substrate: forming a mask over a second side of the glass substrate, wherein the mask covers the TGV holes; and filling the cavities with a fill material.

Example 34 includes the method of any of Examples 27-33, wherein forming the one or more TGVs in the glass substrate comprises, before filling the TGV holes with the conductive material using the electroplating process: forming a mask over the first side of the glass substrate, wherein the mask covers the conductive layer.

Example 35 includes the method of any of Examples 27-34, wherein: the method is a method of forming a package substrate, wherein the package substrate comprises the glass substrate, the TGVs, the cavities, a plurality of interconnect layers, and a plurality of conductive contacts; and the method further comprises: forming the plurality of interconnect layers above and below the glass substrate, wherein the interconnect layers comprise a plurality of dielectric layers, a plurality of conductive traces, and a plurality of vias; and forming the plurality of conductive contacts on one or more surfaces of the package substrate.

Example 36 includes the method of any of Examples 27-35, wherein receiving the glass substrate further comprises forming the one or more TGV holes and the one or more cavities in the glass substrate.

Example 37 includes the method of any of Examples 27-36, wherein the glass substrate comprises silicon, oxygen, and aluminum.

1. A substrate, comprising:
a glass layer comprising a rectangular prism volume;
a cavity in the glass layer; and
one or more vias extending between top and bottom surfaces of the glass layer, wherein the vias are filled with a first conductive material, and wherein sidewalls of the vias are not lined with a second conductive material.

2. The substrate of claim 1, wherein the first conductive material comprises copper.

3. The substrate of claim 1, further comprising passive circuitry at least partially within the cavity, wherein the passive circuitry is to be electrically coupled to a power supply.

4. The substrate of claim 3, further comprising a first dielectric layer, a second dielectric layer, and a third dielectric layer, wherein the first dielectric layer is above the glass layer, wherein the second dielectric layer is below the glass layer, wherein the third dielectric layer is within the cavity, and wherein the passive circuitry is at least partially within the third dielectric layer.

5. The substrate of claim 1, wherein:
the cavity is filled with the first conductive material; or
the cavity comprises residue from the first conductive material.

6. The substrate of claim 1, further comprising one or more tooling holes in the glass layer, wherein the tooling holes are filled with a non-magnetic material.

7. The substrate of claim 1, wherein the vias are seedless through-glass vias.

8. The substrate of claim 1, wherein the sidewalls of the vias are lined with a dielectric material.

9. An electronic device, comprising:
a substrate comprising a glass core, wherein the glass core is not comprised of an organic adhesive or an organic material, wherein the glass core comprises a cavity and one or more through-glass vias (TGVs), wherein the TGVs comprise a conductive fill layer, and wherein the TGVs do not comprise a conductive liner between the conductive fill layer and interior walls of the TGVs; and
an integrated circuit (IC) die electrically coupled to the substrate.

10. The electronic device of claim 9, wherein the substrate further comprises passive circuitry at least partially within the cavity, wherein the passive circuitry is electrically coupled to the IC die, and wherein power is to be delivered to the IC die through the passive circuitry.

11. The electronic device of claim 10, wherein the passive circuitry comprises at least one of an inductor, a capacitor, or a resistor.

12. The electronic device of claim 10, wherein the substrate further comprises a first dielectric layer, a second dielectric layer, and a third dielectric layer, wherein the first dielectric layer is above the glass core, wherein the second dielectric layer is below the glass core, wherein the third dielectric layer is within the cavity, and wherein the passive circuitry is at least partially within the third dielectric layer.

13. The electronic device of claim 9, further comprising:
a circuit board; and
an IC package electrically coupled to the circuit board, wherein the IC package comprises the substrate and the IC die.

14. A method, comprising:
receiving a glass substrate, wherein the glass substrate includes one or more through-glass via (TGV) holes and one or more cavities;
forming a conductive layer over a first side of the glass substrate;
forming one or more TGVs in the glass substrate, wherein the TGV holes are filled with a conductive material using an electroplating process, wherein the conductive layer is a cathode and the conductive material is an anode in the electroplating process; and
removing the conductive layer from the glass substrate.

15. The method of claim 14, wherein:
forming the conductive layer over the first side of the glass substrate comprises:
forming a dielectric layer and the conductive layer over the first side of the glass substrate, wherein the dielectric layer is between the conductive layer and the glass substrate; and
removing the conductive layer from the glass substrate comprises:
removing the dielectric layer and the conductive layer from the glass substrate.

16. The method of claim 15, wherein forming the dielectric layer and the conductive layer over the first side of the glass substrate comprises:
forming a resin copper clad (RCC) layer over the first side of the glass substrate, wherein the RCC layer comprises the dielectric layer and the conductive layer, wherein the dielectric layer comprises resin, and wherein the conductive layer comprises copper.

17. The method of claim 15, wherein forming the one or more TGVs in the glass substrate comprises:
forming a mask over a second side of the glass substrate, wherein the mask covers the cavities;
etching portions of the dielectric layer to expose the conductive layer through the TGV holes; and
filling the TGV holes with the conductive material using the electroplating process.

18. The method of claim 15, wherein forming the one or more TGVs in the glass substrate comprises:
etching portions of the dielectric layer to expose the conductive layer through the TGV holes and the cavities; and
filling the TGV holes and the cavities with the conductive material using the electroplating process.

19. The method of claim 18, wherein forming the one or more TGVs in the glass substrate further comprises:
etching away the conductive material in the cavities.

20. The method of claim 14, further comprising, before forming the one or more TGVs in the glass substrate:
forming a mask over a second side of the glass substrate, wherein the mask covers the TGV holes; and
filling the cavities with a fill material.
